(19) United States
(12) Patent Application Publication
(10) Pub. No.: US 2002/0127849 A1
(43) Pub. Date: Sep. 12, 2002

(54) Method of manufacturing dual damascene structure

(76) Inventors: Chien-Hsing Lin, Taichung (TW); Wen-Yi Hsieh, Hsinchu (TW)

Correspondence Address: J.C. PATENTS INC., 4 VENTURE, SUITE 250, IRVINE, CA, 92618, US

(21) Appl. No.: 09/802,508

(22) Filed: Mar. 9, 2001

(51) Int. Cl. H01L 21/4763

(52) U.S. Cl. 438/638; 438/687

(57) ABSTRACT

A method for manufacturing dual damascene structure is disclosed. A dielectric layer is formed over a substrate having a conductive region. A dual damascene process is carried out to form a trench and a via openings exposing the conductive region in the openings. Sequentially a first barrier metal layer, a second barrier metal layer comprised of tungsten material, and a seed layer are formed over the dielectric layer and covering the sidewalls and the bottom of the trench and the via openings. A conductive metal layer is then blanket deposited over the dielectric layer and the top surface is planarized to remove portions of the conductive metal layer, the seed layer, the second barrier metal layer, and the first barrier metal layer until the dielectric layer is exposed.

### BACKGROUND OF THE INVENTION

1. Filed of Invention

The present invention relates generally to dual damascene structure and more specifically to a method of fabrication of barrier metal layers.

2. Description of Related Art

In the process of manufacturing integrated circuits, after the individual devices, such as the transistors, have been fabricated in the silicon substrate, they must be connected together to perform the desired circuit functions. This connection process is generally called “metallization”, and is performed using a number of different photolithographic and deposition techniques.

One such method is known as dual damascene which basically involves the formation of an opening which is filled in with a metal. Dual damascene techniques involve the formation of an opening comprising a lower contact or via opening section in communication with an upper trench opening section, which opening is filled with a conductive material, typically a metal, to simultaneously form a conductive plug in electrical contact with a conductive line.

The use of the damascene techniques eliminates metal etch and dielectric gap fill steps typically used in the metallization process. The elimination of metal etch steps is important as the semiconductor industry moves from aluminum to other metallization materials, such as copper, which are very difficult to etch.

High performance microprocessor applications require rapid speed of semiconductor circuitry. The speed of semiconductor circuitry varies inversely with the resistance and capacitance of the interconnection pattern. Cu and Cu alloys have received considerable attention as a replacement material for aluminum (Al) in interconnect metallizations. Cu is relatively inexpensive, has a lower resistivity than Al. Accordingly, Cu is a desirable metal for use as a conductive plug as well as wiring. One drawback of using copper is that barrier layers are required. Typical diffusion barrier materials include tantalum (Ta), tantalum nitride (TaN), titanium (Ti), titanium nitride (TiN), titanium-titanium nitride (Ti—TiN). The barrier layers serve several different roles. They promote greater adhesion of the copper to the dielectric layer. They prevent diffusion of copper into the dielectric layer. They improve the resistance of copper to electromigration, which is the movement of copper atoms under the influence of current flow, which can cause voids in the copper.

However there is one problem with the conventional barrier metal layers formed on the sidewall of an opening. The difference in thermal coefficient of expansion between copper and the dielectric layer is large, therefore during the subsequent thermal process, the thermal stress due to thermal expansion is large. Consequently, the conventional barrier layers is not strong enough to resist the thermal expansion and are fractured causing defects due to diffusion of copper and electromigration.

### SUMMARY OF THE INVENTION

The present invention provides a method to improve the adhesion ability between the dielectric layer and the conductive layer so that fracturing or cracking of the barrier metal layer can be effectively prevented.

The present invention provide a method to improve the adhesion between the dielectric layer and the conductive layer of an opening so that fracturing or cracking of the barrier metal layer can be effectively prevented and thereby the reliability of the device can be substantially increased.

The present invention provides an additional CVD tungsten layer to enhance the barrier metal strength so that fracturing or cracking of the barrier metal layer can be effectively prevented.

In accordance with the foregoing, the present invention provides an additional barrier metal layer in between the barrier metal layer and the seed layer on sidewalls and bottom of opening to increase the adhesion between the dielectric layer and the conductive layer in the opening. As a result, the barrier metal layer is capable of resisting the thermal stress due to thermal expansion of the dielectric layer and the conductive layer. Thus, fracturing of cracking of the barrier metal layer can be effectively prevented and thereby the reliability of the semiconductor device is substantially increased.

In accordance to the preferred embodiment, a semiconductor substrate having at least one conductive region formed thereon is provided. A dielectric layer composed of a low dielectric constant is formed over the substrate. A dual damascene fabrication technique is carried out to form a via opening and a trench over the via opening, exposing the conductive region within the via opening. A first barrier metal layer, a second barrier metal layer and a seed layer are sequentially formed on the dielectric layer and on the sidewalls and the bottom of the trench and the via. A conductive layer is next formed over the seed layer and filling the trench and the via openings. CMP process is performed to remove portions of the conductive metal layer, the seed layer, the second barrier metal layer, and the first barrier metal layer until the dielectric layer is exposed. The second barrier layer comprises of tungsten. The tungsten metal is selected for forming the second barrier layer because of its excellent adhesion property, and its higher hardness and strength properties compared to the materials such as copper which are filled in the via and the trench.

A method for manufacturing a dual damascene structure is provided by the present invention in which a second tungsten barrier metal layer is formed between the barrier metal layer and the seed layer of an opening. Since tungsten metal has a very good adhesion property, it promotes adhesion between the dielectric layer and the conductive layer. And since the strength and hardness of tungsten metal is greater compared to conductive layers such as aluminum, copper, or gold, it renders the barrier metal layer very strong. Because the tungsten metal promotes adhesion between the dielectric layer and the conductive layer and also renders the barrier strong, the barrier metal layer are capable of resisting the thermal stress due to thermal expansion of the dielectric layer and the conductive layer. Thus fracturing or cracking of barrier layer can be effectively prevented. Thus the reliability of the semiconductor device can be substantially increased.

The above and additional advantages of the present invention will become apparent to those skilled in the art from the following detailed description when taken in conjunction with the accompanying drawings.

### BRIEF DESCRIPTION OF THE DRAWINGS

FIGS. 1A through 1D are schematic, cross sectional views showing the progression of manufacturing steps in fabricating barrier metal layers in accordance with the present invention.

### DESCRIPTION OF THE PREFERRED EMBODIMENTS

Reference will be made in detail to the present preferred embodiments of the invention, examples of which are illustrated in the accompanying drawings. Wherever possible, the same reference numbers are used in the drawings and the description to refer to the same or like parts.

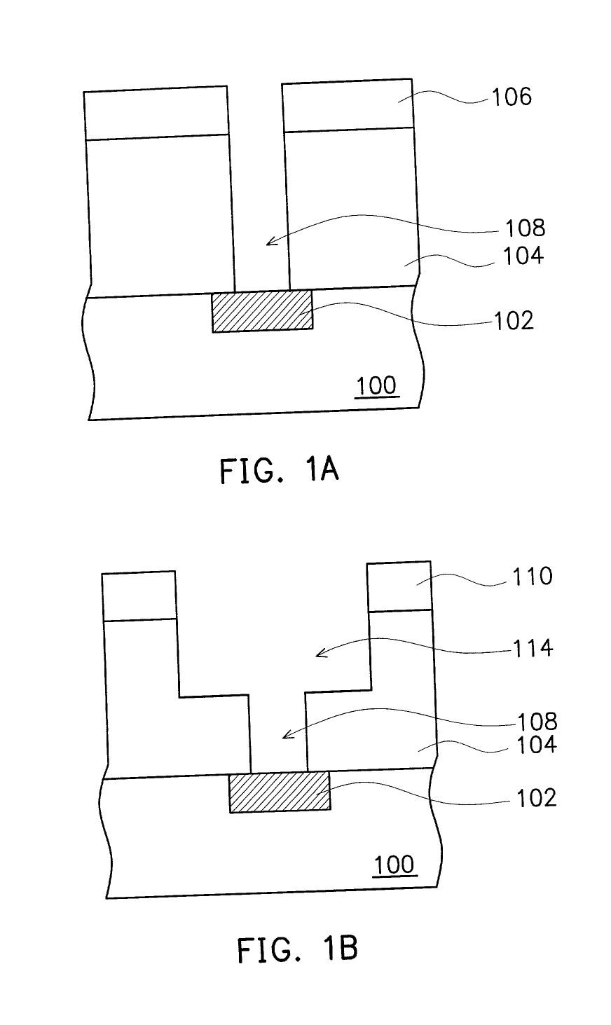

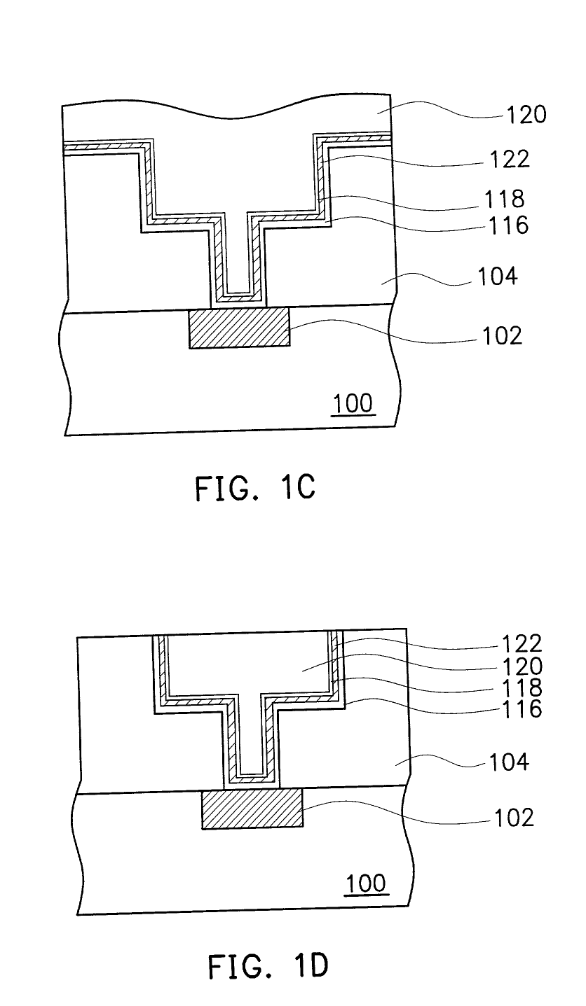

FIG. 1A through 1D are schematic, cross sectional views showing the progression of manufacturing steps in fabricating barrier layers in accordance with the present invention.

Referring to FIG. 1A, a substrate 100 is provided. The substrate 100 at least having a conductive region 102, for example a gate structure, a wire or a source/drain region. A dielectric layer 104 composed of low dielectric constant material, for example spin-on-polymers (SOP) materials, is formed over the conductive region 102. A CMP process is performed to planarize the dielectric layer 104. A patterned photoresist layer 106 is formed over the dielectric layer 104 and using the photoresist layer 106 as a mask, the dielectric layer 104 is etched to form a via opening 108 over the conductive region 102 and exposing the conductive region 102 within the opening 108.

Referring to FIG. 1B, the patterned photoresist layer 106 is then removed, or stripped. A patterned photoresist layer 110 is placed over the low dielectric layer 104 and using the patterned photoresist layer 110 as mask, the dielectric layer 104 is etched by using a time controlled etching step to form a trench 114 over the via 108.

Referring to FIG. 1C, the patterned photoresist layer 110 is then removed. A first barrier metal layer 116, for example titanium (Ti), titanium nitride (TiN), tantalum (Ta), tantalum nitride (TaN) is then deposited over the dielectric layer 104, the trench 114 and the via opening 108, for example, the barrier metal layer 116 is deposited using a conventional metal deposition technique, such as chemical vapor deposition (CVD) method. A second barrier metal layer 122, is deposited on the first barrier metal layer 116, for example, the second barrier metal layer 122 comprises of tungsten (W) of thickness of about 100 to 200 angstroms, is deposited by using a CVD method. Next, a seed layer 118, is formed on the second barrier metal layer 122. A conductive layer 120, for example copper is deposited over the dielectric layer 104 filling the trench 114 and the via 108 using a conventional metal deposition technique, such as electro-chemical deposition (ECD) method.

Since tungsten metal 122 has a very good adhesion property, it promotes adhesion between the dielectric layer 104 and the conductive layer 120. And since the strength and hardness of tungsten metal 122 is greater compared to conductive layers such as aluminum, copper, or gold, it renders the first barrier layer 116 very strong. Because the tungsten metal promotes adhesion between the dielectric layer 104 and the conductive layer 120 and also renders the barrier metal layer 116 strong, the first barrier metal layer 116 is capable of resisting the thermal stress due to thermal expansion of the dielectric layer and the conductive layer. Thus fracturing or cracking of the first barrier metal layer 116 can be effectively prevented.

Referring to FIG. 1D, a second chemical-mechanical polishing process is performed to remove portions of the conductive layer 120, the seed layer 118, the second barrier metal layer 122, and the first barrier metal layer 116 until the dielectric layer 104 is exposed.

With the approach of the present invention, the tungsten barrier metal layer 122 is formed in between the first barrier metal layer 116 and the seed layer 118. Since tungsten metal has a very good adhesion property, it promotes adhesion between the dielectric layer 104 and the conductive layer 120. And since the strength and hardness of tungsten metal is greater compared to conductive layers such as aluminum, copper, or gold, it enhances the first barrier layer 116 strength ability. Because the tungsten metal promotes adhesion between the dielectric layer 104 and the conductive layer 120 and also renders the first barrier metal layer 116 strong, the first barrier metal layer 116 is capable of resisting the thermal stress due to thermal expansion of the dielectric layer and the conductive layer. Thus fracturing or cracking of barrier metal layer 116 can be effectively prevented. Consequently, the reliability of the device can be substantially increased.

While the best mode utilizes copper as the conductive material, it should be understood that the present invention is applicable to other conductive materials such as copper, aluminum, silver, gold, and the barrier layer can be of tantalum, tantalum nitride, titanium, and titanium nitride.

Further, although the embodiments of the present invention are directed to using the dual damascene technique, it also will be recognized by those skilled in the art that other techniques of forming interconnect, such as the single damascene technique, or other traditional techniques of forming contacts or plugs which involve filling an opening with conductive materials such as tungsten or aluminum may be used to practice the present invention.

While the invention has been described in conjunction with a specific best mode, it is to be understood that many alternatives, modifications, and variations will be apparent to those skilled in the art in light of the a foregoing description. Accordingly, it is intended to embrace all such alternatives, modifications, and variations which fall within the spirit and scope of the included claims. All matters set forth herein or shown in the accompanying drawings are to be interpreted in an illustrative and non-limiting sense.

It is to be understood that the foregoing general description and the following detailed description are exemplary, and are intended to provide further explanation of the invention as claimed.

What is claimed is:

1. A method of manufacturing a dual damascene structure, the method comprising the steps of:
providing a semiconductor substrate having a conductive region formed thereon;
forming a dielectric layer over the substrate;
forming a via opening and a trench in the dielectric layer, wherein the trench is formed over the via opening and the conductive region is exposed within the via opening;
forming a first barrier metal layer over the dielectric layer, the trench and the via openings;
forming a second barrier metal layer on the first barrier metal layer;
forming a seed layer on the additional barrier metal layer; and
forming a conductive layer over the seed layer, and filling the trench and the via openings, wherein the material of the second barrier metal layer is of higher strength and hardness compared to the conductive layer so that the first barrier metal strength ability is enhanced.

2. The method according to claim 1, wherein the second barrier metal layer comprises a material made of tungsten.

3. The method according to claim 2, wherein the second barrier metal layer is formed by performing a chemical vapor deposition process.

4. The method according to claim 2, wherein the thickness of the second barrier metal layer is about 100 to 200 angstroms.

5. The method according to claim 1, wherein the material of the conductive layer is selected from a group consisting of copper, aluminum, silver, gold, and alloys thereof.

6. The method according to claim 1, wherein the material of the first barrier metal layer is selected from a group consisting of tantalum, tantalum nitride, titanium, and titanium nitride.

7. The method according to claim 1, wherein the material of the dielectric layer is selected from a group consisting of spin-on-polymers.

8. The method according to claim 1, wherein the dielectric layer is made of spin-on-polymer material, the first barrier metal layer is made of titanium nitride material, the second barrier metal layer is made of tungsten material, and the conductive layer is a copper material.

9. The method according to claim 1, wherein the conductive region comprises a gate, a wire, or a source/drain region.

10. A method for fabricating a damascene structure, the method comprising the steps of:
providing a semiconductor substrate having a conductive region formed thereon;
forming a dielectric layer over the substrate;
forming an opening in the dielectric layer, wherein the conductive region is exposed within the opening;
forming a first barrier metal layer over the dielectric layer and the opening;
forming a second barrier metal layer on the first barrier metal layer;
forming a seed layer on the second barrier metal layer; and
forming a conductive layer over the seed layer and filling the opening, wherein the material of the second barrier metal layer is of higher strength and hardness compared to the conductive layer so that the first barrier metal layer strength ability is enhanced.

11. The method according to claim 10, wherein the second barrier metal layer comprises of a material made of tungsten.

12. The method according to claim 11, wherein the thickness of the second barrier metal layer is about 100 to 200 angstroms.

13. The method according to claim 11, wherein the second barrier metal layer is formed by performing an chemical vapor deposition process.

14. The method according to claim 10, wherein the material of the conductive layer is selected from a group consisting of copper, aluminum, silver, gold, and alloys thereof.

15. The method according to claim 10, wherein the material of the first barrier metal layer is selected from a group consisting of aluminum, tantalum nitride, titanium, and titanium nitride.

16. The method according to claim 10, wherein the material of the dielectric layer is selected from a group consisting of spin-on-polymer.

17. The method according to claim 10, wherein the dielectric layer is made of spin-on-polymer material, the first barrier metal layer is made of titanium nitride material, the second barrier metal layer is made of tungsten material, and the conductive layer is a copper layer.

18. The method according to claim 10, wherein the conductive region comprises a gate, a wire, or a source/drain region.
